(19) United States
(12) Patent Application Publication
(10) Pub. No.: US 2013/0260182 A1
(43) Pub. Date: Oct. 3, 2013

(54) PCB with Both High and Low Current Traces for Energy Storage Modules

(71) Applicants: Andrew A. Knitt, Deer Creek, IL (US); Wellington Ying-Wei Kwok, Dunlap, IL (US)

(72) Inventors: Andrew A. Knitt, Deer Creek, IL (US); Wellington Ying-Wei Kwok, Dunlap, IL (US)

(73) Assignee: Caterpillar, Inc., Peoria, IL (US)

(21) Appl. No.: 13/430,824

(22) Filed: Mar. 27, 2012

(51) Int. Cl. H01M 2/00; H05K 1/11; H01K 3/10; H05K 7/06; H01G 9/00; H05K 1/00; H01G 9/155

(52) U.S. Cl. 429/7; 174/250; 174/266; 361/502; 361/728; 361/434; 29/852

(57) ABSTRACT

A printed circuit board (PCB) for an energy storage module is disclosed which includes a first side having a plurality of low current traces useful for monitoring and balancing applications and a second side coated with high current traces, useful for current or power transmission purposes. Vias connect the high current traces to the low current traces thereby electrically connecting both sides of the board together. The disclosed PCB is particularly useful for energy storage modules whereby monitoring and/or balancing of the modules is required in addition to the transmission of high current levels for power applications.

### BACKGROUND

1. Technical Field

This disclosure relates to printed circuit boards (PCBs) with low current connections for component monitoring on one side of the board and high current connections for connecting energy storage cells in series on the other side of the board.

2. Description of the Related Art

Construction, agricultural and mining machines are generally powered by internal combustion engines. However, internal combustion engines emit undesirable exhaust emissions and other pollutants during operation. For the foreseeable future, the reduction of exhaust emissions from internal combustion engines will be a regulatory priority. Furthermore, increasing fuel efficiency of machines has also become of increased importance, for example, to reduce costs associated with the rising price of oil and/or reliance on imported oil.

Driven by new and future emissions regulations and fuel consumption concerns, alternative ways to power machines have been sought. One such alternative is the use of power trains having electric components such as, for example, electric motors, generators, and electronic control systems. Electric components have been used previously in passenger vehicle power train applications. However, the construction of such electric components for use in off-highway environments presents challenges not associated with passenger vehicles. Essentially, the electric components must be made more robust and therefore more reliable.

Printed circuit boards (PCBs) are widely used to mechanically support and electrically connect electric components and electronic circuits. PCBs are inexpensive and highly reliable in various applications including transportation devices, such as automobiles. When used in automobile applications, PCBs are used for many purposes including control circuits, monitoring circuits, junction boxes and power distribution.

PCBs may connect electronic components and electronic circuits using conductive pathways, or “traces”. Traces may be etched from copper sheets which are laminated onto a non-conductive substrate. A wide variety of solid state electronic components, including resistors, capacitors, thyristors, rectifiers, diodes and transistors can be connected to the PCB and electrically to each other through such traces. Traces which handle higher current levels must be thicker or have a larger cross-sectional area than traces for low current applications.

To provide the electrical connection between the electrical component and the traces, it is common to use electrical wiring. An electrical connector may be connected to the end of the wire which in turn is connected to the traces. Although these types of connections generally perform well, for certain relatively high electrical current applications (e.g., power distribution within a vehicle), the traces and lining must have a sufficient thickness to handle these relatively high current levels.

While PCBs can be relatively inexpensive to manufacturer, PCBs incorporating traces capable of handling high current levels are expensive to manufacture due to the larger amount of trace material and the increased manufacturing cost. Specifically, traces for laminate circuit boards are often formed of thin copper plating or foil, often in the range about 0.0015 to about 0.0028 inches (about 0.038 to about 0.071 mm) in thickness. These thicknesses are well suited for carrying relatively low currents, e.g., up to about six (6) amps for traces with widths of about 0.1 inch (about 2.5 mm), but are susceptible to overheating if higher currents are carried. Thus, conventional traces cannot be used to carry current sufficient to power a machine.

In the development of bussed electrical modules (BEM), both high-current and low-current circuits are required in the same module. In the past, as shown in U.S. Pat. No. 7,957,156, surface-mounted bus bars have been employed to form high-current paths where needed. However, bus bars are manufactured separately and must then be assembled and soldered to the PCB, incurring additional material and assembly costs.

The connecting together of individual battery cells for high-voltage, high-energy applications is known. While batteries are somewhat power-limited because the chemical reaction that takes place within a battery limits the rate at which batteries can accept energy during charging and supply energy during discharging. Regardless, the use of battery packs or modules are used in hybrid vehicles, pure electric vehicles and other applications.

Ultracapacitors are an alternative to batteries because they can also be connected together, for high-voltage applications. Ultracapacitors have an extended life of hundreds of thousands of charge/discharge cycles. However, while ultracapacitor modules are typically more expensive than battery packs for the same applications, ultracapacitor packs or modules are projected to last the life of the vehicle or machine. Ultracapacitor modules also may offer better fuel-efficient operation than battery modules in hybrid applications through braking regeneration energy capture and being more efficient at supplying vehicle acceleration power.

Battery modules and ultracapacitor modules have been built in various forms and configurations. Various wiring harnesses, bus bars, and connections have been used for current routing and voltage monitoring. In a traditional battery or ultracapacitor module assembly, high-current bus bar and intercell connections are typically made directly to the cell terminals either by mechanical means (e.g., bolts, pins, etc.) or permanent welds. Low-current circuitry for monitoring, balancing and other related control functions are designed and implemented on a PCB as a “separate structure”, and then mechanically attached to the high-current bus bar using screws, pins, clips, etc. Although this conventional method is well-known, it necessitates the use of separate and often a large number of small parts (e.g., M2 or M3 screws), and secondary assembly steps, which also may lead to potential reliability issue as the same subassembly or new “contacts” would have been repeated for multiple times. For example, a typical high-voltage (e.g., 300-360V) hybrid or electric vehicle battery or ultracapacitor module contains a minimum of 90-150 individual cells, i.e., 180 to 300 high-current bus bar connections directly to the cell terminals. In addition to these 180-300 high-current/high-power connections, it is necessary to make another 180-300 low-current connections between the PCBs to the bus bars or integrated to the high-current connection point (e.g., additional ring terminals, etc.).

Accordingly, it would be desirable if high current routing were available on PCBs, that does not require the placement of a discrete components, such as bus bars and the associated large number of small parts, and that is compatible with the processing with thin copper traces on the same PCB that can be used for low current applications.

### SUMMARY OF THE DISCLOSURE

In one aspect, a printed circuit board (PCB) is disclosed which includes a board having a first side and a second side. The first side includes at least one low current trace. The second side includes at least one high current trace. The board also includes at least one via connecting the at least one high current trace to the at least one low current trace.

In another aspect, an energy storage module is disclosed which includes a PCB including a board that has a first side and a second side. The first side includes a plurality of low current traces. The second side includes a plurality of high current traces. The board further includes a plurality of pairs of vias. At least some of the vias connect at least one of the high current traces to at least one of the low current traces. The energy storage cell module further includes a plurality of storage cells, such as ultracapacitors or batteries, with terminal pairs. The terminals of each storage cell is mounted in one of the plurality of pairs of vias.

In yet another aspect, a method is disclosed for electrically connecting low current traces on a first side of a printed circuit board to high current traces disposed on an opposite second side of the board and for mounting electrical components to the board. The method includes providing through holes in the board. The method further includes coating the through holes with a conducting material and without clogging the through holes to convert the through holes into combination vias and through holes. The method further includes printing low current traces on the first side of the board wherein at least one of the low current traces is in contact with at least one of the vias. The method further includes printing high current traces on the second side of the board. At least one of the high current traces is in contact with said at least one of the vias to provide current to the at least one of the low current traces on the first side of the board. The method further includes providing a plurality of energy storage cells, such as ultracapacitors or batteries. Each storage cell includes a pair of terminals. The method also includes mounting the plurality of storage cells to the board by inserting each terminal of each storage cell into one of the through holes.

In any one or more of the embodiments described above, the via or vias also serve as openings or through holes for mounting a component to the board. The component may be an ultracapacitor or a battery. In embodiments where the component is an ultracapacitor or battery and wherein the ultracapacitor or battery has two terminals, the vias/through holes may be formed in pairs so an ultracapacitor or battery may be mounted to the board by inserting the terminals into a pair of vias/through holes. In such embodiments, the vias may be formed by forming a through hole in the board and coating the through hole with conductive material to thereby provide an electrical connection between one side of the board and the other side of the board.

In any one or more of the embodiments described above, the low current traces may have a first thickness and the high current traces may have a second thickness and a ratio of the second thickness to the first thickness may range from about 10:1 to about 20:1.

In any one or more of the embodiments described above, the high current trace or high current traces can transmit at least 200 amps.

In any one or more of the embodiments described above, the first side of the PCB may provide storage module monitoring and/or a storage module balancing functions.

In any one or more of the embodiments described above, the second side of the PCB may be used to transmit current to be used to operate a machine.

In any one or more of the embodiments described above, the low and/or high current traces may be formed from copper.

### BRIEF DESCRIPTION OF THE DRAWINGS

FIG. 1 is a sectional view of a PCB made in accordance with this disclosure showing an inner signal layer of the PCB.

FIG. 2 is a top view of the PCB, particularly illustrating through holes/vias for accommodating ultra capacitors and providing an electrical connection between the top side of the PCB shown in FIG. 2 and the bottom side of the PCB shown in FIG. 3.

FIG. 3 is a bottom view of the PCB shown in FIG. 2.

FIG. 4 is a perspective view of an ultracapacitor energy storage module that may utilize PCBs as disclosed in FIGS. 1 and 2.

FIG. 5 is a perspective view of a cylindrical battery that can be utilized with the PCB shown in FIGS. 1 and 2.

FIG. 6 is a perspective view of six cylindrical ultracapacitors that can be utilized with the PCB shown in FIGS. 1 and 2.

FIG. 7 is a perspective view of a prismatic battery that can be utilized with the PCB shown in FIGS. 1 and 2.

FIG. 8 is a perspective view of another prismatic battery that can be utilized with the PCB shown in FIGS. 1 and 2.

FIG. 9 is a top perspective view of a prismatic ultracapacitor that can be utilized with the PCB shown in FIGS. 1 and 2.

### DETAILED DESCRIPTION OF THE PRESENTLY PREFERRED EMBODIMENTS

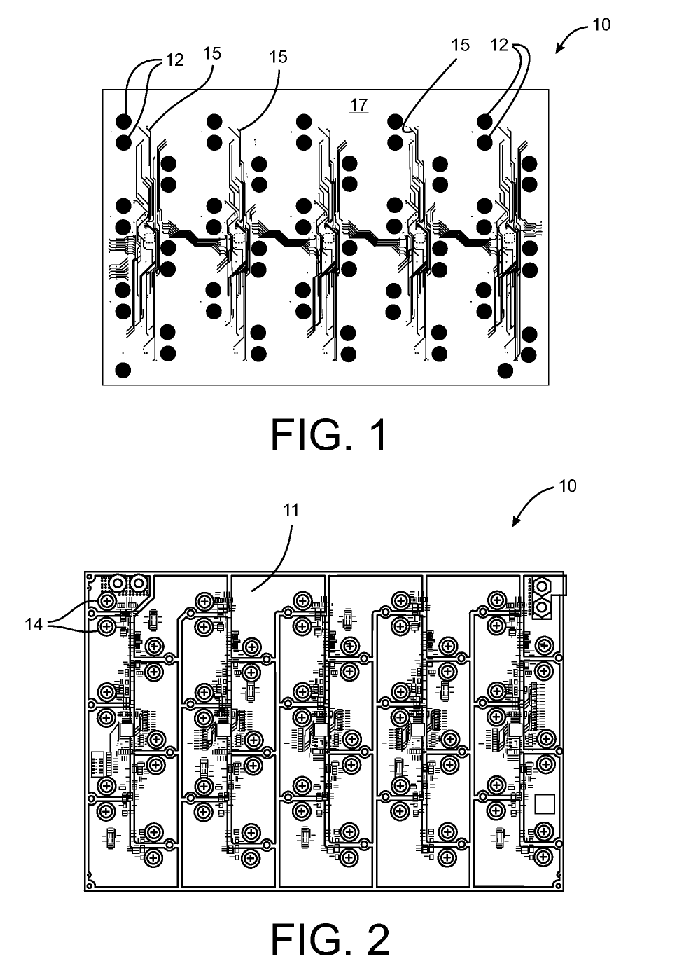

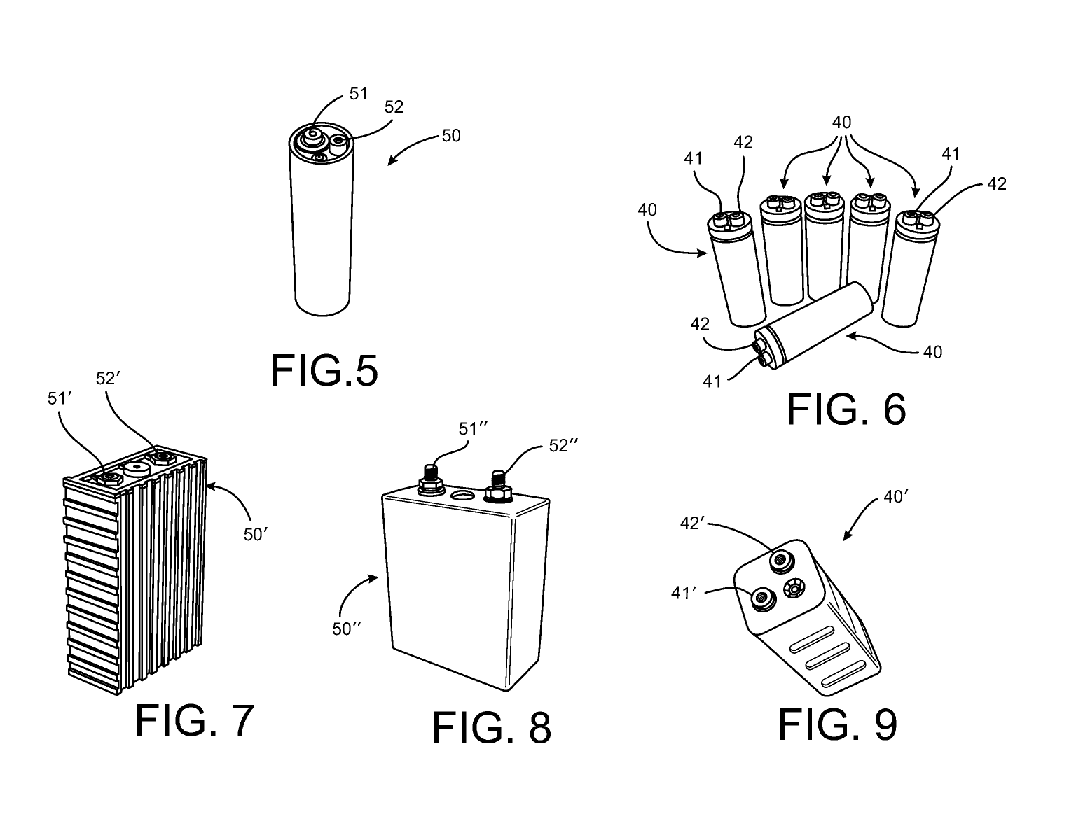

Turning to FIG. 1, an inner signal layer 17 of a PCB 10 is disclosed which includes a plurality of through holes 12 that are grouped in pairs as shown in FIG. 1. The through holes 12 are provided in pairs as the through holes are used for dual purposes. First, the through holes are used as vias as discussed below. Second, the through holes 12 are used for mounting terminals of an ultracapacitor or battery to the first side 11 of the PCB 10 as shown in FIG. 2. Specifically, typical ultracapacitors 40, 40′ or batteries 50, 50′, 50″ shown in FIGS. 5-9 include a pair of terminals 41, 42, 41′, 42′, 51, 52, 51′, 52′, 51″, 52″. The terminals 41, 42, 41′, 42′, 51, 52, 51′, 52′, 51″, 52″ may be received in the through holes 12.

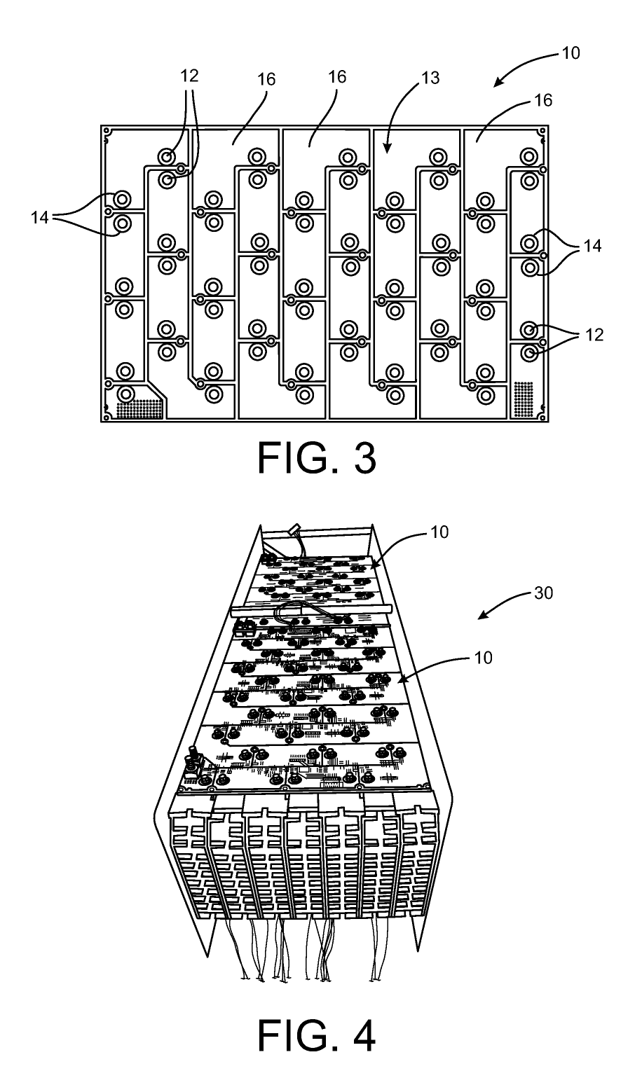

The bottom view of the PCB 10 is shown in FIG. 3. The PCB 10 includes a bottom or second side 13 through which the through holes 12 extend as shown. Also shown in FIG. 3 is the conductive coating 14 provided on each through hole 12. The conductive coating 14 renders each through hole 12 a via thereby providing electrical communication between the first side 11 (FIG. 2) and the second side 13 of the PCB 10 (FIG. 3).

Returning to FIG. 1, a plurality of low current traces 15 are shown. Returning to FIG. 3, instead of low current traces 15, the second side 13 of the PCB 10 includes thickened copper sections 16 capable of transmitting high current levels, e.g., 200 amps or more. In one embodiment, the low current traces 15 and the high current traces 16 are both copper or copper-based. The coatings 14 of the through holes 12 may also be copper or copper-based. The first side 11 of the PCB 10 (FIG. 2) may be utilized for monitoring purposes or cell monitoring while the second side 13 of the PCB 10 (FIG. 3) may be used to transmit current used to power a vehicle, machine or other apparatus that is powered or partially-powered by the energy storage module 30 of FIG. 4.

Turning to FIG. 4, the storage module 30 includes a plurality of PCBs 10, a plurality of ultracapacitors 40 or batteries 50 (not shown in FIG. 4). The storage module 30 may also include a plurality of PCBs 10, two of which is shown in FIG. 3.

Finally, FIG. 5 illustrates a cylindrical battery 50 with terminals 51, 52 having internal threads. FIG. 6 illustrates six ultracapacitors 40 having terminals 41, 42 with internal threads. FIG. 7 illustrates a prismatic battery 50′ having terminals 51′, 52′ with internal threads. FIG. 8 illustrates another prismatic battery 50″ having terminals 51″, 52″ that are studs having external threads. Finally, FIG. 9 illustrates yet another ultracapacitor 40′ having terminals 41′, 42′ with internal threads. Both batteries and ultracapacitors may be utilized with the PCB 10 and the terminals may be of the internal thread type (FIGS. 5-7 and 9) or the stud type (FIG. 8).

### INDUSTRIAL APPLICABILITY

A printed circuit board is disclosed that is suitable for use in monitoring the functions of an energy storage module as well as for transmitting high levels of current provided by ultracapacitors, batteries or any other type of energy storage device. The PCB includes a first side and a second side. The first side includes a plurality of low current traces used with various components, as will be apparent to those skilled in the art, for monitoring the performance of or balancing the storage module. The second side of the PCB includes thick conductive layers for transmitting current provided by ultracapacitors, batteries or other types of storage cells that form part of the storage module.

Electrical communication between the first and second sides of the PCB is provided by vias. However, the vias may have a dual function. Specifically, the vias may be formed from large through holes that receive the terminals of the ultracapacitors, batteries or other type of energy storage cell. The through holes are coated with a conductive lining that provides electrical communication between the high current second side of the PCB and the low current/monitoring first side of the PCB. The use of one side of the PCB to transmit high levels of current for power purposes avoids the need for a bus bar. Bus bars, which have traditionally been used on PCBs for transmitting high current levels, must be fabricated separately and attached to the PCB in a separate soldering or other attachment procedure. Further, some conventional designs require the PCBs and bus bars to be disposed in separate locations. In contrast, the disclosed PCBs enable thinner low current traces to be deposited by conventional means on the first side of the PCB and also enable thicker conductive layers to be deposited on the second side of the PCB using conventional deposition technology, that will be apparent to those skilled in the art. One such provider of deposition technologies that can produce low current traces on one side of a PCB and thicker high current coatings on the other side of the same PCB is available from UPE, Inc. of Richfield, Ohio (www.upe-inc.com).

1. A printed circuit board (PCB), comprising:
a board including a first side and a second side, the first side including at least one low current trace, the second side including at least one high current trace, the board further including at least one via connecting the at least high current trace to the at least one low current trace.

2. The PCB of claim 1 wherein the at least one via is also an through hole for mounting a component on the board.

3. The PCB of claim 1 wherein the component is an energy storage device including at least one terminal that is received in the at least one via.

4. The PCB of claim 3 wherein the energy storage device is an ultracapacitor or a battery.

5. The PCB of claim 3 wherein the energy storage device includes two terminals and the board further comprises two vias for receiving the two terminals of the energy storage device, each via connecting at least one high current trace on the second side of the board to at least one low current trace on the first side of the board.

6. The PCB of claim 1 wherein the at least one low current trace has a first thickness and the at least one high current trace has a second thickness, a ratio of the second thickness to the first thickness ranging from about 10:1 to about 20:1.

7. The PCB of claim 1 wherein the at least one high current trace can transmit at least 200 amps.

8. The PCB of claim 1 wherein the first side of the PCB is a storage cell module monitoring circuit board.

9. The PCB of claim 1 wherein the first side of the PCB is a storage cell module balancing board.

10. An energy storage module, comprising:
a printed circuit board (PCB) including a board including a first side and a second side, the first side including a plurality of low current traces, the second side including a plurality of high current traces, the board further including a plurality of pairs of vias, at least some of the vias connecting at least one of the high current traces to at least one of the low current traces; and
a plurality of energy storage cells, each energy storage cell being mounted in one of the plurality of pairs of vias.

11. The energy storage module of claim 10 wherein each via connects at least one high current trace on the second side of the board to at least one low current trace on the first side of the board.

12. The energy storage module of claim 10 wherein each low current trace has a thickness and each high current trace has a thickness, a ratio of the thicknesses of the high current traces to the low current traces ranging from about 10:1 to about 20:1.

13. The energy storage module of claim 10 wherein the high current traces can transmit at least 200 amps.

14. The energy storage module of claim 10 wherein the first side of the PCB is a storage module monitoring circuit board.

15. The energy storage module of claim 10 wherein the second side of the PCB transmits current to be used to operate a machine.

16. The energy storage module of claim 10 wherein the low and high current traces include copper.

17. A method for electrically connecting low current traces on a first side of a printed circuit board to high current traces disposed on an opposite second side of the board and for mounting electrical components to the board, the method comprising:
providing through holes in the board;
coating the through holes with a conducting material and without clogging the through holes to convert the through holes into vias and through holes;
printing low current traces on the first side of the board, at least one of the low current traces being in contact with at least one of the vias; and
printing high current traces on the second side of the board, at least one of the high current traces being in contact with said at least one of the vias to provide current to said at least one of the low current traces on the first side of the board;
providing a plurality of energy storage cells, each energy storage cell including a pair of terminals;
mounting the plurality of energy storage cells to the board by inserting each terminal of each energy storage cell into one of the through holes.

18. The method of claim 17 wherein the printing of the low current traces includes printing the low current traces so the low current traces have a thickness and the printing of the high current traces includes printing the high current traces so the high current traces have a thickness, a ratio of the thicknesses of the high current traces to the low current traces ranging from about 10:1 to about 20:1.

19. The method of claim 17 wherein the first side of the PCB is a energy storage module monitoring circuit board and the second side of the PCB transmits current to be used to operate a machine.

20. The method of claim 17 wherein the energy storage cells are selected from the group consisting of ultracapacitors, batteries or a combination thereof.
